(19) United States
(12) Patent Application Publication
(10) Pub. No.: US 2026/0136688 A1
(43) Pub. Date: May 14, 2026

(54) RADIATION DETECTOR, DETECTION UNIT, RADIATION IMAGING SYSTEM, AND METHOD FOR MANUFACTURING DETECTION UNIT

(71) Applicant: CANON KABUSHIKI KAISHA, Tokyo (JP)

(72) Inventors: FUMIAKI MIZUTANI, Kanagawa (JP); ZEMPEI WADA, Saitama (JP); TAKANORI WATANABE, Kanagawa (JP)

(21) Appl. No.: 18/937,151

(22) Filed: Nov. 5, 2024

(30) Foreign Application Priority Data
Nov. 7, 2023 (JP) 2023-190403

(51) Int. Cl. H10F 39/00; H10F 39/18

(52) U.S. Cl. CPC H10F 39/028; H10F 39/1898; H10F 39/804; H10F 39/805; H10F 39/811

(57) ABSTRACT

A radiation detector includes, in plan view, a first region including a pixel portion and configured to detect a radiation by the pixel portion including a plurality of pixels, a second region including a plurality of peripheral circuits, and a third region provided between the first region and the second region. A mark portion is disposed in the first region or the third region. The mark portion includes at least one of a first portion and a second portion. The first portion constitutes a surface layer of the radiation detector. The second portion is a portion of a lower layer adjacent to the first portion.

### BACKGROUND

### Technical Field

The present disclosure relates to a radiation detector, a detection unit, a radiation imaging system, and a method for manufacturing a detection unit.

### Description of the Related Art

A radiation detector including a semiconductor substrate on which pixels and peripheral circuits are formed is known. When a radiation is incident on a peripheral circuit region, the radiation can cause erroneous operation of the peripheral circuits or malfunction of the peripheral circuits. Therefore, a shielding member that shields the radiation such that the radiation is not incident on the peripheral circuits is provided in the radiation detector. The shielding member has an opening provided at a position corresponding to a pixel region of the radiation detector. Therefore, the radiation detector and the shielding member need to be aligned such that the radiation is incident on the pixels through the opening of the shielding member.

In contrast, Japanese Patent Application Laid-Open No. 2019-197839 and Japanese Patent Application Laid-Open No. 2010-212471 disclose image sensors for light detection that are not configured to detect a radiation. Japanese Patent Application Laid-Open No. 2019-197839 discloses that when manufacturing an image sensor, a mark for alignment is provided in a process for photolithography in order to merge divided regions in step-and-repeat exposure with high precision. In addition, Japanese Patent Application Laid-Open No. 2010-212471 discloses forming the mark for alignment for aligning a lens with respect to a photodiode.

However, it is difficult to align the radiation detector and the shielding member by using the alignment marks described in Japanese Patent Application Laid-Open No. 2019-197839 and Japanese Patent Application Laid-Open No. 2010-212471. If the positions of the radiation detector and the shielding member are not aligned, there is a possibility that the shielding member does not overlap with the peripheral circuit region and a radiation is incident on the peripheral circuit region.

### SUMMARY

The present disclosure provides a technique advantageous for aligning a radiation detector and a shielding member.

According to one aspect of the present disclosure, a radiation detector includes, in plan view, a first region including a pixel portion and configured to detect a radiation by the pixel portion including a plurality of pixels, a second region including a plurality of peripheral circuits, and a third region provided between the first region and the second region. A mark portion is disposed in the first region or the third region. The mark portion includes at least one of a first portion and a second portion. The first portion constitutes a surface layer of the radiation detector. The second portion is a portion of a lower layer adjacent to the first portion.

Further features of the present invention will become apparent from the following description of exemplary embodiments with reference to the attached drawings.

### BRIEF DESCRIPTION OF THE DRAWINGS

FIG. 1 is a schematic diagram illustrating a configuration of a radiation detector according to a first embodiment.

FIG. 2A is a plan view of the radiation detector according to the first embodiment.

FIG. 2B is an exploded perspective view of a detection according to the first embodiment.

FIG. 3A is a section view of the radiation detector according to the first embodiment.

FIG. 3B is an explanatory diagram of a mark portion according to the first embodiment.

FIG. 3C is an explanatory diagram of the mark portion according to the first embodiment.

FIG. 4A is an explanatory diagram of a mark portion of a modification example of the first embodiment.

FIG. 4B is an explanatory diagram of a mark portion of a modification example of the first embodiment.

FIG. 4C is an explanatory diagram of a mark portion of a modification example of the first embodiment.

FIG. 4D is an explanatory diagram of a mark portion of a modification example of the first embodiment.

FIG. 4E is an explanatory diagram of a mark portion of a modification example of the first embodiment.

FIG. 4F is an explanatory diagram of a mark portion of a modification example of the first embodiment.

FIG. 5A is a section view of a radiation detector according to a second embodiment.

FIG. 5B is an explanatory diagram of a mark portion according to the second embodiment.

FIG. 5C is an explanatory diagram of the mark portion according to the second embodiment.

FIG. 6A is a section view of a radiation detector according to a third embodiment.

FIG. 6B is an explanatory diagram of a mark portion according to the third embodiment.

FIG. 6C is an explanatory diagram of the mark portion according to the third embodiment.

FIG. 7A is a section view of a radiation detector according to a fourth embodiment.

FIG. 7B is an explanatory diagram of a mark portion according to the fourth embodiment.

FIG. 7C is an explanatory diagram of the mark portion according to the fourth embodiment.

FIG. 8A is a section view of a radiation detector according to a fifth embodiment.

FIG. 8B is an explanatory diagram of a mark portion according to the fifth embodiment.

FIG. 9A is a plan view of the radiation detector according to a sixth embodiment.

FIG. 9B is a plan view of a detection unit according to the sixth embodiment.

FIG. 10A is a section view of the radiation detector according to the sixth embodiment.

FIG. 10B is an explanatory diagram of a mark portion according to the sixth embodiment.

FIG. 10C is an explanatory diagram of the mark portion according to the sixth embodiment.

FIG. 11A is a plan view of a detection unit according to a modification example of the sixth embodiment.

FIG. 11B is a plan view of a detection unit according to a modification example of the sixth embodiment.

FIG. 12 is a diagram illustrating a system according to a seventh embodiment.

FIG. 13A is a diagram illustrating a system according to an eighth embodiment.

FIG. 13B is a diagram illustrating the system according to the eighth embodiment.

### DESCRIPTION OF THE EMBODIMENTS

Embodiments of the present disclosure will be described below with reference to drawings. To be noted, the present invention is not limited to the embodiments below, and can be appropriately modified within the gist thereof. In addition, in the drawings described below, elements having the same functions will be denoted by the same reference signs, and description thereof will be omitted.

In the description below, “radiation” is a concept including ionized radiations (X-ray and gamma ray) and particle beam radiations (electron beam, proton beam, neutron beam, alpha ray, and the like). “Radiation imaging system” generally refers to a system that obtains an image of an imaging target (object, patient in the case of a medical imaging system, and the like) as electronic data by using a radiation. The “image” may be a still image or a moving image. “Radiation detector” refers to an image sensor unit (also referred to as a camera or an imaging portion) that is a constituent element of a radiation imaging system and that obtains an image as electronic data by converting a radiation image of an imaging target into an electric signal.

### First Embodiment

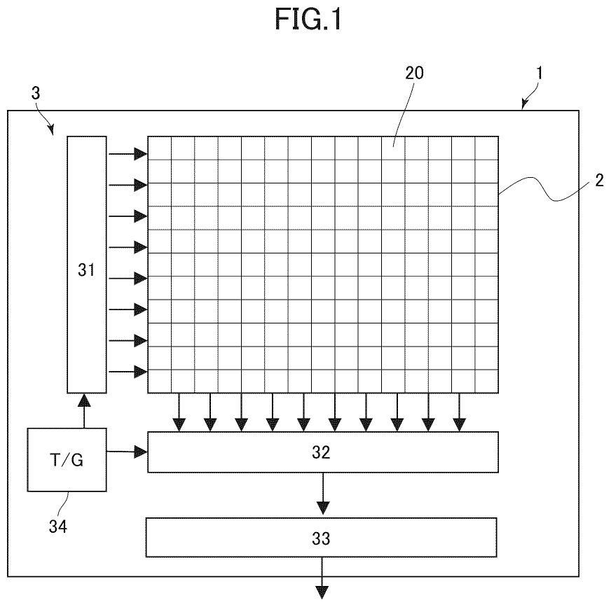

FIG. 1 is a schematic diagram illustrating a configuration of a radiation detector 1 according to a first embodiment. The radiation detector 1 is an image sensor, for example, a complementary metal oxide semiconductor (CMOS) image sensor. The radiation detector 1 includes a pixel array 2 serving as an example of a pixel portion, and a peripheral circuit portion 3.

The pixel array 2 includes a plurality of pixels 20 arranged in an array shape. The plurality of pixels 20 include effective pixels each including a detection diode. Each pixel 20 accumulates charges generated by a radiation that the pixel has received, and outputs a pixel signal (analog signal) corresponding to the amount of accumulated charges. To be noted, the plurality of pixels 20 may include non-effective pixels and/or dummy pixels. Here, the effective pixel is a pixel used for image generation, and is positioned in an effective pixel region (imaging region). The non-effective pixel is a pixel that is positioned in a region (non-effective pixel region) other than the effective pixel region, and is not used for image generation. The dummy pixel is a pixel not including a detection diode.

The peripheral circuit portion 3 includes a plurality of peripheral circuits. For example, the peripheral circuit portion 3 includes peripheral circuits such as a vertical scan circuit 31, a readout circuit 32, a signal output circuit 33, and a timing generator 34. The timing generator 34 controls the operation of each of the circuits 31 and 32 by a control signal. The vertical scan circuit 31 sequentially selects the pixels 20 of the pixel array 2 on a row basis. The readout circuit 32 includes an A/D conversion circuit, and converts a pixel signal, which is an analog signal read out from the pixel 20, into a digital signal. The signal output circuit 33 outputs the pixel signal converted into a digital signal to an external apparatus. To be noted, the peripheral circuit portion 3 may additionally include peripheral circuits such as a column amplifier, a correlated double sampling (CDS) circuit, and an adder circuit.

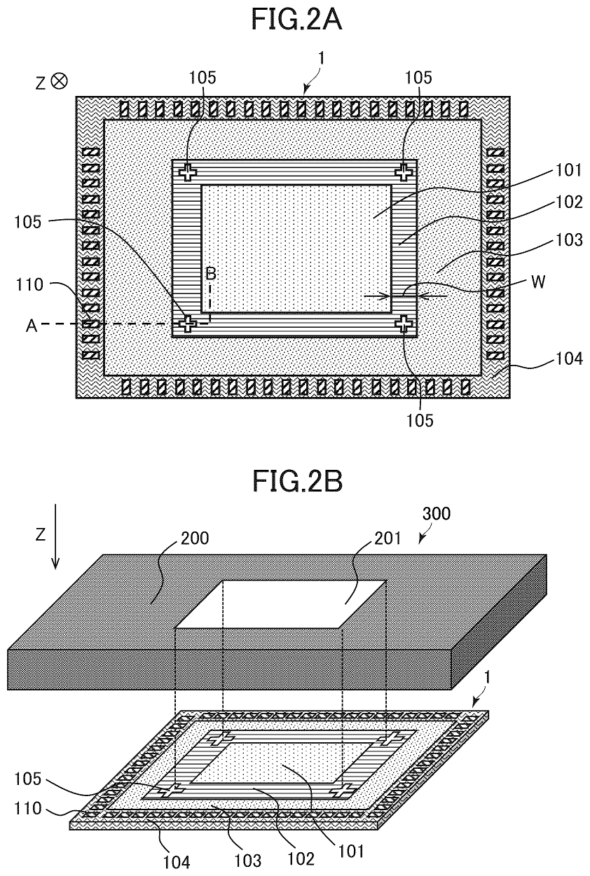

FIG. 2A is a plan view of the radiation detector 1 according to the first embodiment. FIG. 2A illustrates a surface (incident surface) on the radiation incident side of the radiation detector 1 in plan view, that is, as viewed in a Z direction. The Z direction is a direction orthogonal to the incident surface of the radiation detector 1, and is a direction toward the incident surface.

The radiation detector 1 is segmented into a plurality of regions as viewed in the Z direction. The plurality of regions include a pixel region 101, a buffer region 102, a peripheral circuit region 103, and a pad region 104. The pixel region 101 is a region including the pixel array 2. The peripheral circuit region 103 is a region including the peripheral circuit portion 3, and is a region positioned outside the pixel region 101. The buffer region 102 is a region between the pixel region 101 and the peripheral circuit region 103. The pad region 104 is a region positioned outside the peripheral circuit region 103. Neither the pixel array 2 nor the peripheral circuit portion 3 is present in the buffer region 102.

The pixel region 101 is a region having a rectangular shape. The buffer region 102 is a region having a quadrangular frame shape, and is adjacent to the pixel region 101 so as to surround the pixel region 101. The peripheral circuit region 103 is a region having a quadrangular frame shape, and is adjacent to the buffer region 102 so as to surround the buffer region 102. The pad region 104 is a region having a quadrangular frame shape, and is adjacent to the peripheral circuit region 103 so as to surround the peripheral circuit region 103. In the pad region 104, a plurality of pad electrodes 110 for electrically connecting to a driving board or the like including a power source (power source circuit) by wire bonding are provided. The pixel region 101 is an example of a first region. The peripheral circuit region 103 is an example of a second region. The buffer region 102 is an example of a third region.

At least one mark portion is disposed in the buffer region 102 as viewed in the Z direction. The at least one mark portion is preferably two or more mark portions. In the first embodiment, for example, four mark portions 105 are disposed as the at least one mark portion in the buffer region 102. Each mark portion 105 is disposed in the vicinity of corresponding one of four corner portions of the buffer region 102 as viewed in the Z direction. To be noted, the position of the mark portion 105 is not limited to the vicinity of a corner portion of the buffer region 102. For example, a plurality of mark portions may be disposed in a distributed manner all over the buffer region 102.

The pixel region 101 includes an isolation region and an active region. Further, the plurality of pixels 20 illustrated in FIG. 1 are two-dimensionally arranged in the pixel region 101.

Here, if a radiation is incident on the peripheral circuit region 103, there is a possibility that a peripheral circuit in the peripheral circuit portion 3 is charged up. In addition, there is a possibility that a defect occurs in a boundary between an insulating layer and a semiconductor substrate and the defects serves as a cause of dark current, a possibility that an electron generated by the radiation flows into a peripheral circuit to cause a latch-up, and the like. Due to these factors, there is a possibility that erroneous operation of a peripheral circuit or malfunction of a peripheral circuit occurs. Therefore, in the first embodiment, a shielding member shielding a radiation such that no radiation is incident on the peripheral circuits is provided in the radiation detector 1.

FIG. 2B is an exploded perspective view of a detection unit 300 according to the first embodiment. The detection unit 300 includes the radiation detector 1 and a shielding member 200. The shielding member 200 is formed from a metal member capable of shielding a radiation. The shielding member 200 is disposed on the radiation incident side of the radiation detector 1. The shielding member 200 is disposed at a position overlapping with the entirety of the peripheral circuit region 103, that is, the entirety of the peripheral circuit portion 3 illustrated in FIG. 1 as viewed in the Z direction such that no radiation is radiated onto the peripheral circuit region 103.

An opening 201 that is a through hole is provided in the shielding member 200. The opening 201 is formed at a position corresponding to the pixel array 2 such that the radiation is incident on the pixel array 2.

The opening 201 has a rectangular shape having a larger area than the pixel region 101 as viewed in the Z direction. That is, the pixel array 2 disposed in the pixel region 101 does not overlap with the shielding member 200 as viewed in the Z direction. The pixel array 2 disposed in the pixel region 101 is irradiated with a radiation having passed through the opening 201 of the shielding member 200. The mark portion 105 is used for aligning the shielding member 200 with the radiation detector 1 such that the shielding member 200 does not overlap with the pixel array 2.

Here, misalignment, variation in the shape of the opening 201 of the shielding member 200, the radiation spreading through the opening 201 of the shielding member 200 to the peripheral circuit region 103, and the like need to be considered in the alignment between the radiation detector 1 and the shielding member 200. Therefore, the buffer region 102 serving as an alignment margin is provided between the pixel region 101 and the peripheral circuit region 103 in the radiation detector 1.

If it is easy to visually recognize and focus on the mark portion 105 in the measurement of the mark portion 105 for positioning the shielding member 200, the cost of a system for aligning the radiation detector 1 and the shielding member 200 can be reduced, or the precision of the system can be improved.

Increasing a width W of the buffer region 102 as viewed in the Z direction increases the alignment margin and facilitates the alignment between the radiation detector 1 and the shielding member 200, but this increases the size of the semiconductor substrate 100. In addition, increasing the width W of the buffer region 102 increases the length of the wiring for pixel signals and control signals between the pixel region 101 and the peripheral circuit region 103, which can lead to decrease in the communication speed of the signals. Therefore, by improving the alignment precision between the radiation detector 1 and the shielding member 200, the width W of the buffer region 102 can be reduced, which can lead to reduction of the manufacturing cost of the radiation detector 1 and increase in the communication speed of the signals.

In consideration of the scattering of the radiation incident on the radiation detector 1, the width W of the buffer region 102 is preferably 200 μm or more. In addition, in consideration of the communication speed of the pixel signal and the control signal in the buffer region 102, the width W of the buffer region 102 is preferably 2000 μm or less.

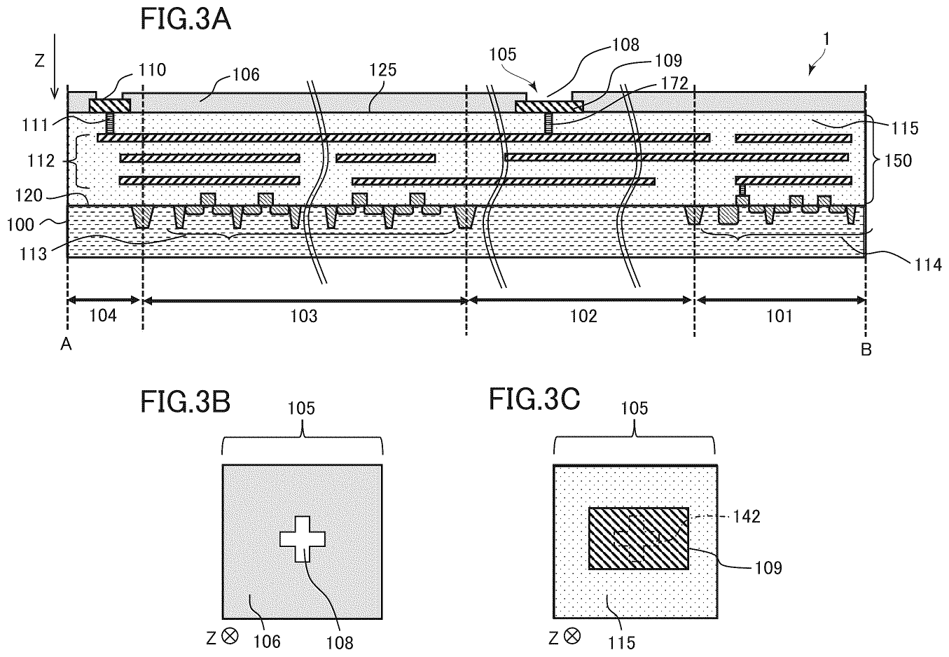

FIG. 3A is a section view of the radiation detector 1 taken along a line A-B of FIG. 2A. The radiation detector 1 includes the semiconductor substrate 100 and a wiring structure body 150 including an interlayer insulating layer 115 disposed on the semiconductor substrate 100 and formed from an insulator, and a plurality of wiring layers (conductor layers) 112 disposed in the interlayer insulating layer 115.

The semiconductor substrate 100 includes the pixel array 2 and the peripheral circuit portion 3 illustrated in FIG. 1. At least part of the pixel array 2 and the peripheral circuit portion 3 is formed on the semiconductor substrate 100.

In addition, a wiring pattern (conductor pattern) 109, a passivation layer 106, and the pad electrodes 110 are disposed on a main surface 125 of the interlayer insulating layer 115. The passivation layer 106 is adjacent to the wiring pattern 109 and the interlayer insulating layer 115, and is a layer protecting members of the radiation detector 1, for example, the wiring pattern 109 and the interlayer insulating layer 115. That is, the wiring pattern 109 is in contact with the main surface 125 of the interlayer insulating layer 115, and the passivation layer 106 is in contact with part of the main surface 125 of the interlayer insulating layer 115 that is not in contact with the wiring pattern 109.

Here, in a CMOS image sensor for light detection, there is a case where a color filter layer for color recognition and a microlens layer for light condensation on each pixel are disposed on the interlayer insulating layer. However, since the radiation detector 1 is used for detecting radiation, the color filter layer and the microlens layer do not need to be provided.

Examples of the material of the passivation layer 106 include organic insulating materials such as silicon oxide, silicon nitride, silicon oxynitride, and polyimide, and combinations of two or more of these materials. Examples of the material of the conductor pattern of each of the outermost wiring layer and the wiring layer 112 include copper, aluminum, tungsten, tantalum, titanium, polysilicon, and alloys including at least one of these metals. Examples of the material of the interlayer insulating layer 115 include silicon oxide, borophosphosilicate glass (BPSG), phosphosilicate glass (PSG), borosilicate glass (BSG), silicon nitride, silicon carbide, and combinations of two or more of these insulating materials.

Control signals such as a vertical signal, a reset signal, and a selection signal can be communicated through the wiring pattern 109, the pad electrodes 110, the wiring layers 112, vias 111, and vias 172. Part of wiring interconnecting the pixel array 2 and the peripheral circuit portion 3 is disposed in the buffer region 102. In addition, the mark portion 105 is disposed in the buffer region 102. The opening 201 of the shielding member 200 is positioned in accordance with the mark portions 105. Since there is a possibility that part of the buffer region 102 is irradiated with the radiation, the members provided in the buffer region 102 preferably have a resistance to irradiation with radiations.

The main surface 120 of the semiconductor substrate 100 is in contact with the interlayer insulating layer 115. A detection diode for detecting a radiation, and a transistor 114 configured to output a detection signal of the detection diode are disposed on the semiconductor substrate 100. In addition, a gate of the transistor 114 is disposed on a main surface 120 of the semiconductor substrate 100. The detection diode and the transistor 114 are included in each of the effective pixels and non-effective pixels among the plurality of pixels 20 (FIG. 1), and are positioned in the pixel region 101 as viewed in the Z direction.

To be noted, the structure of the pixel 20 may be a direct connection type constituted by three transistors, or a transfer type including four transistors in which connection to a gate electrode of an amplification transistor is established through a transistor that transfers charges accumulated in the diode. A structure having advantageous characteristics can be selected in accordance with the use of the radiation detector 1.

In addition, since the pixel region 101 is irradiated with a radiation, it is preferable that the transistors in the pixel region 101 are designed in consideration of radiation resistance. In addition, radiations have a nature of being transmitted through the wiring and the transistors. For example, in the case where the radiation is an electron beam, even if wiring or a transistor is disposed on the detection diode, the detection diode can detect the electron beam because the electron beam reaches the detection diode.

In addition, a transistor 113 constituting a peripheral circuit, for example, a signal processing circuit included in the peripheral circuit portion 3, is disposed on the semiconductor substrate 100, and the gate of the transistor 113 is disposed on the main surface 120 thereof. The transistor 113 is positioned in the peripheral circuit region 103 as viewed in the Z direction. As described above, the peripheral circuit portion 3 including a plurality of peripheral circuits is disposed in the peripheral circuit region 103, and the peripheral circuit portion 3 is shielded from the radiation by the shielding member 200 illustrated in FIG. 2B.

As described above, a plurality of pad electrodes 110 are disposed in the pad region 104. The pad electrodes 110 are disposed on the outermost wiring layer. In other words, the pad electrodes 110 and the wiring pattern 109 are disposed in the layer of the same height. The pad electrodes 110 are provided on the main surface 125 of the interlayer insulating layer 115 in correspondence with an opening of the passivation layer 106, and is electrically connected to a driving board or the like disposed on the outside of the radiation detector 1 through a wire. To be noted, the pad electrodes 110 may be, by using through wiring, electrically connected to the driving board from a surface on the side opposite to the side on which the passivation layer 106 is provided.

The mark portion 105 disposed in the buffer region 102 will be described. FIGS. 3B and 3C are explanatory diagrams of the mark portion 105. FIG. 3B is a plan view of a region of the passivation layer 106 including the mark portion 105 as viewed in the Z direction. FIG. 3C is a plan view of a region of the wiring pattern 109 and the interlayer insulating layer 115 including the mark portion 105 as viewed in the Z direction.

In the first embodiment, the mark portion 105 is a plus-shaped mark in plan view, that is, as viewed in the Z direction. The mark portion 105 is constituted by an opening 108 of the passivation layer 106 and the wiring pattern 109. In the first embodiment, the opening 108 is a through hole penetrating the passivation layer 106. The opening 108 has a plus shape as viewed in the Z direction.

The wiring pattern 109 is a solid pattern having a larger area than the opening 108 as viewed in the Z direction. In the wiring pattern 109, a portion corresponding to the opening 108 constitutes the mark portion 105. In the wiring pattern 109, a region 142 visually recognized through the opening 108 constitutes the mark portion 105.

As described above, the mark portion 105 is a recess portion including the opening 108 of the passivation layer 106 and the wiring pattern 109 that is provided on the outermost wiring layer that is a lower layer adjacent to the passivation layer 106 and that is visually recognized through the opening 108. The passivation layer 106 and the opening 108 thereof are an example of a first portion, and the wiring pattern 109 is an example of a second portion. Here, the outermost wiring layer constitutes part of the outermost layer of the radiation detector 1.

A manufacturing method for the detection unit 300 illustrated in FIG. 2B will be described. First, the radiation detector 1 and the shielding member 200 are prepared.

Next, the mark portion 105 is measured by using a measurement apparatus such as a microscope from the incident surface side of the radiation detector 1. In the first embodiment, since the mark portion 105 serving as a standard for alignment is provided, the mark portion 105 can be easily optically measured, and the focus of the measurement apparatus can be also easily adjusted.

Next, the shielding member 200 is aligned with the radiation detector 1 such that the peripheral circuit region 103 of the radiation detector 1 is covered by the shielding member 200 as viewed in the Z direction. Specifically, the shielding member 200 is aligned with the radiation detector 1 such that the shielding member 200 overlaps with part or entirety of each mark portion 105 and the shielding member 200 does not overlap with the pixel array 2 (pixel region 101) as viewed in the Z direction. Then, the shielding member 200 and the radiation detector 1 are fixed. In the first embodiment, the shielding member 200 is aligned with the radiation detector 1 so as to overlap with the entirety of each mark portion 105.

At the time of this alignment, since the visibility of the mark portion 105 is high, the shielding member 200 can be aligned with the radiation detector 1 with high precision. For example, by aligning a corner of the opening 201 of the shielding member 200 with a corner of the mark portion 105 having a plus shape as illustrated in FIG. 2B, each mark portion 105 overlaps with the shielding member 200, and the shielding member 200 can be aligned with the radiation detector 1 with high precision.

As described above, according to the first embodiment, a technique advantageous for alignment between the radiation detector 1 and the shielding member 200 is provided. Further, since the visibility of the mark portion 105 is high, the shielding member 200 can be aligned with the radiation detector 1 with high precision.

In addition, as a result of the radiation being shielded by the shielding member 200, the radiation being incident on the peripheral circuit portion 3 in the peripheral circuit region 103 can be suppressed, the circuit of the peripheral circuit portion 3 being charged up can be suppressed, and malfunction of the circuit of the peripheral circuit portion 3 can be suppressed. In addition, in the peripheral circuit region 103, generation of a defect in the interface between the interlayer insulating layer 115 and the semiconductor substrate 100 can be reduced, and generation of a dark current can be reduced. As a result of this, the operation of the circuit of the peripheral circuit portion 3 is stabilized. In addition, electrons generated by irradiation with the radiation flowing to the circuit of the peripheral circuit portion 3 can be suppressed, and thus occurrence of erroneous operation such as a latch-up can be suppressed. As a result of this, the operation of the circuit of the peripheral circuit portion 3 is stabilized. In addition, since the pixel array 2 disposed in the pixel region 101 does not overlap with the shielding member 200 as viewed in the Z direction, occurrence of an image defect can be suppressed.

### Modification Examples of First Embodiment

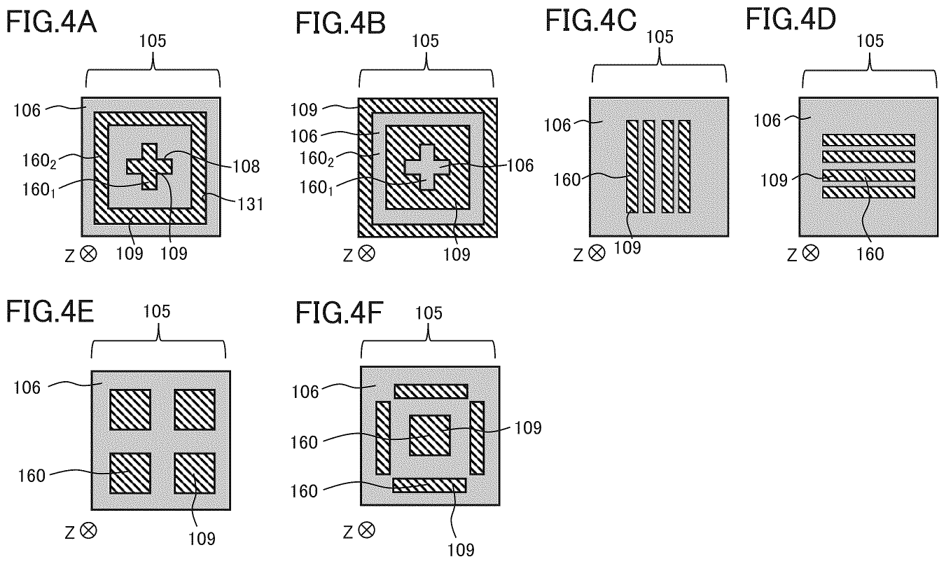

Modification examples of the mark portion 105 of the first embodiment will be described. Although a case where the mark portion 105 is a mark of a plus shape has been described in the first embodiment, the shape is not limited to this. The shape of the mark portion 105 may be, for example, an L shape, an H shape, a quadrangular shape, a quadrangular frame shape, or the like. In addition, the mark portion 105 may be a combination of a plurality of marks. FIGS. 4A to 4F are explanatory diagrams of the mark portion 105 of modification examples.

The mark portion 105 illustrated in FIG. 4A includes a mark 160₁ having a plus shape, and a mark 160₂ having a quadrangular frame shape surrounding the mark 160₁ of the plus shape. The passivation layer 106 has an opening 108 (through hole) having a plus shape, and an opening 131 (through hole) having a quadrangular frame shape. A wiring layer 121 includes the wiring pattern 109. The mark 160₁ of a plus shape is constituted by the opening 108 and the wiring pattern 109, and the mark 160₂ having a quadrangular frame shape is constituted by the opening 131 and the wiring pattern 109.

When aligning the shielding member 200 with the radiation detector 1, the mark 160₂ having a frame shape is measured at a low magnification ratio, and thus the shielding member 200 is aligned with the radiation detector 1 with low precision. Then, the mark 160₁ having a plus shape is measured at a high magnification ratio, and thus the shielding member 200 is aligned with the radiation detector 1 with high precision. Then, the shielding member 200 and the radiation detector 1 are fixed, and thus the detection unit 300 is manufactured.

The mark portion 105 illustrated in FIG. 4B is a mark portion in which the opening and non-opening of the passivation layer 106 in the mark portion 105 illustrated in FIG. 4A are swapped. The mark portion 105 illustrated in FIG. 4B is selected in accordance with the visibility and the layout of members.

The mark portion 105 illustrated in FIG. 4C includes a plurality of marks 160 each having a rectangular shape. The plurality of marks 160 illustrated in FIG. 4C each have a rectangular shape having a long side parallel to the up-down direction of FIG. 4C. The plurality of marks 160 illustrated in FIG. 4C are arranged at intervals in the left-right direction.

The mark portion 105 illustrated in FIG. 4D includes a plurality of marks 160 each having a rectangular shape. The plurality of marks 160 illustrated in FIG. 4D each have a rectangular shape having a long side parallel to the left-right direction of FIG. 4D. The plurality of marks 160 illustrated in FIG. 4D are arranged at intervals in the up-down direction.

In the example of FIG. 2A, the mark portion 105 illustrated in FIG. 4C may be disposed in a region longer in the up-down direction in the buffer region 102, and the mark portion 105 illustrated in FIG. 4D may be disposed in a region longer in the left-right direction in the buffer region 102. As a result of this, the alignment adjustment of the shielding member 200 in the rotational direction about an irradiation direction of the radiation can be performed by using the long sides of the marks 160 of FIG. 4C or FIG. 4D, and the shielding member 200 can be aligned with high precision in the rotational direction.

The mark portion 105 illustrated in FIG. 4E and the mark portion 105 illustrated in FIG. 4F each include a plurality of marks 160, and can be also used for another process such as a photolithography process in addition to the alignment of the shielding member 200. For example, the mark portion 105 illustrated in FIG. 4E can be used as a mark for defining a dicing line in a dicing process of a semiconductor chip. In addition, for example, the mark portion 105 illustrated in FIG. 4F can be used as a mark for measuring superimposition precision in the photolithography process. A production mask for forming the mark portion 105 can be simplified by employing these mark portions 105.

### Second Embodiment

A radiation detector according to a second embodiment will be described with reference to drawings. In the second embodiment, description of matter common to the first embodiment will be simplified or omitted, and difference from the first embodiment will be mainly described. The schematic configuration of the radiation detector 1 of the second embodiment is as described in the first embodiment with reference to FIGS. 1 and 2A. In addition, the schematic configuration of the detection unit 300 including the radiation detector 1 and the shielding member 200 of the second embodiment is as described in the first embodiment with reference to FIG. 2B.

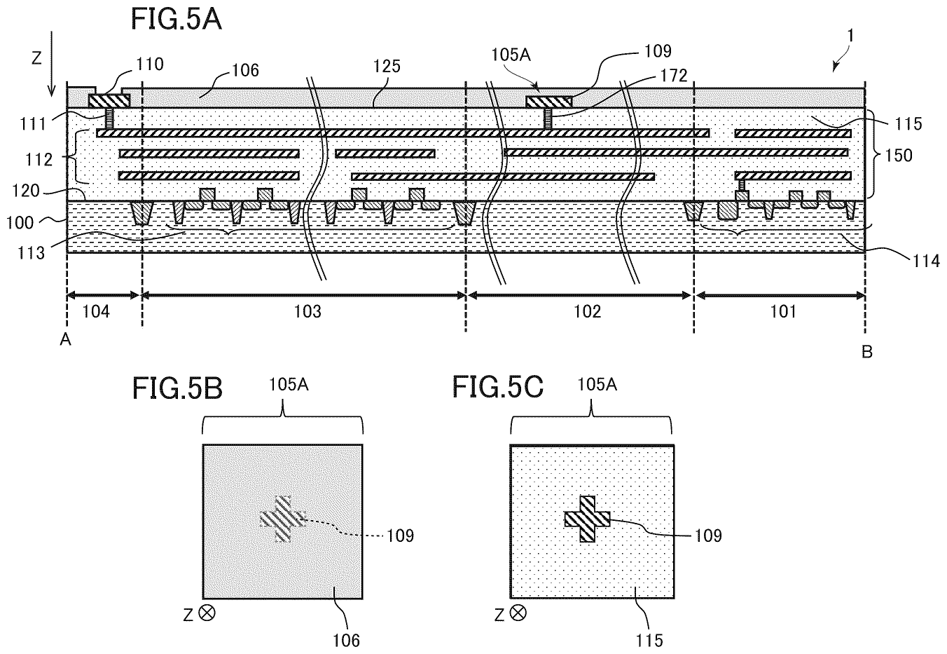

FIG. 5A is a section view of the radiation detector 1 taken along a line A-B of FIG. 2A.

The wiring structure body 150 of the second embodiment includes the interlayer insulating layer 115 formed from an insulator and the plurality of wiring layers (conductor layers) 112 disposed in the interlayer insulating layer 115. In addition, the wiring pattern 109 of the outermost wiring layer is disposed on the interlayer insulating layer 115, and the passivation layer 106 is disposed on the interlayer insulating layer 115 and the wiring pattern 109. The passivation layer 106 is adjacent to the wiring pattern 109 and the interlayer insulating layer 115. That is, the wiring pattern 109 is in contact with the main surface 125 of the interlayer insulating layer 115, and the passivation layer 106 is in contact with part of the main surface 125 of the interlayer insulating layer 115 that is not in contact with the wiring pattern 109. The passivation layer 106 is a surface layer, and the wiring pattern 109 is a lower layer under the passivation layer 106. A mark portion 105A is disposed in the buffer region 102 as viewed in the Z direction.

FIGS. 5B and 5C are explanatory diagrams of the mark portion 105A. FIG. 5B is a plan view of a region of the passivation layer 106 including the mark portion 105A as viewed in the Z direction. FIG. 5C is a plan view of a region of the wiring pattern 109 and the interlayer insulating layer 115 including the mark portion 105A as viewed in the Z direction.

The mark portion 105A includes part of the wiring pattern 109 adjacent to the passivation layer 106 (surface layer). In the second embodiment, the mark portion 105A is constituted by the wiring pattern 109.

That is, in the second embodiment, the mark portion 105A is an upper layer on the wiring pattern 109, and does not include an insulating portion of the passivation layer 106. The wiring pattern 109 is covered by the passivation layer 106.

In the second embodiment, the mark portion 105A is a plus-shaped mark in plan view, that is, as viewed in the Z direction. That is, the wiring pattern 109 has a plus shape as viewed in the Z direction.

To be noted, the method for manufacturing the detection unit 300 according to the second embodiment is as described in the first embodiment, and the description thereof will be omitted.

In the second embodiment, the wiring pattern 109 is covered by the passivation layer 106.

The passivation layer 106 transmits light of a wavelength range of visible light. That is, the passivation layer 106 is transparent or translucent for the wavelength range of visible light. Therefore, light can pass through the passivation layer 106 even if the mark portion 105A is covered by the passivation layer 106 as illustrated in FIG. 5B, and therefore the mark portion 105A can be visually recognized in light measurement.

The wiring pattern 109 may be part of the wiring. The wiring pattern 109 may be used as a ground electrode, and does not affect a signal line and a control line much. In addition, the degree of freedom of design of the mark portion 105A is high in terms of the shape and size thereof. Further, since the wiring pattern 109 is covered by the passivation layer 106, the second embodiment is more advantageous than the first embodiment in terms of humidity resistance and surface protection.

As described above, according to the second embodiment, a technique advantageous for the alignment between the radiation detector 1 and the shielding member 200 can be provided. Further, since the visibility of the mark portion 105A is high, the shielding member 200 can be aligned with the radiation detector 1 with high precision. In addition, as a result of the radiation being shielded by the shielding member 200, the circuit operation of the peripheral circuit portion 3 is stabilized, malfunction of the peripheral circuit portion 3 is suppressed, and occurrence of an image defect is also suppressed.

To be noted, various modifications may be made to the mark portion 105A of the second embodiment similarly to the first embodiment. For example, the mark portion 105A can be modified as in the modification examples illustrated in FIGS. 4A to 4F.

### Third Embodiment

A radiation detector according to a third embodiment will be described with reference to drawings. In the third embodiment, description of matter common to the first embodiment will be simplified or omitted, and difference from the first embodiment will be mainly described. The schematic configuration of the radiation detector 1 of the third embodiment is as described in the first embodiment with reference to FIGS. 1 and 2A. In addition, the schematic configuration of the detection unit 300 including the radiation detector 1 and the shielding member 200 of the third embodiment is as described in the first embodiment with reference to FIG. 2B.

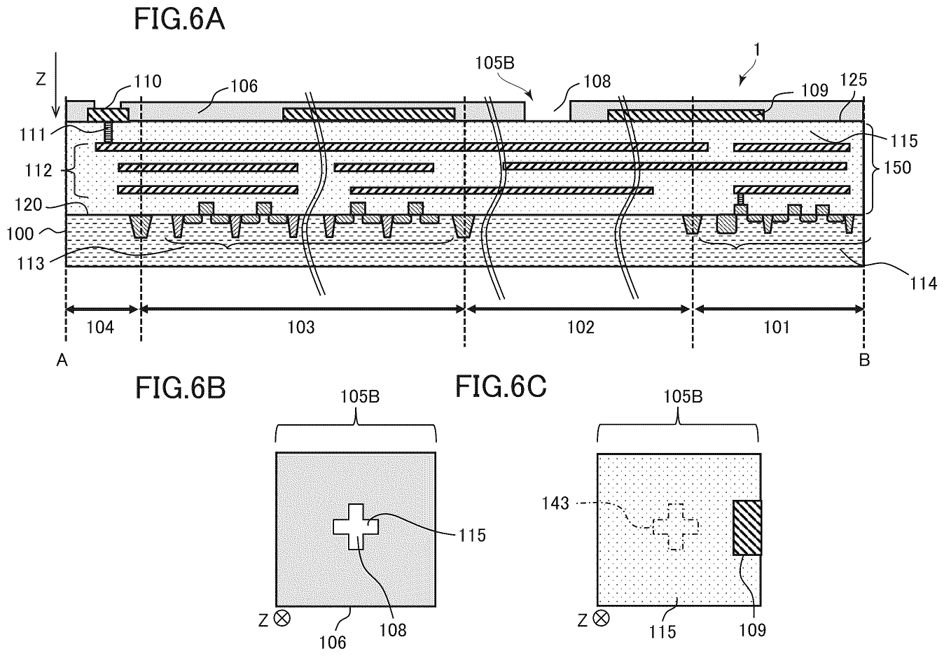

FIG. 6A is a section view of the radiation detector 1 taken along the line A-B of FIG. 2A.

The wiring structure body 150 of the third embodiment includes the interlayer insulating layer 115 formed from an insulator and the plurality of wiring layers (conductor layers) 112 disposed in the interlayer insulating layer 115. In addition, the wiring pattern 109 that is part of the outermost wiring layer is disposed on the interlayer insulating layer 115, and the passivation layer 106 is disposed on the interlayer insulating layer 115 and the wiring pattern 109. The passivation layer 106 is adjacent to the wiring pattern 109 and the interlayer insulating layer 115.

That is, the wiring pattern 109 is in contact with the main surface 125 of the interlayer insulating layer 115, and the passivation layer 106 is in contact with part of the main surface 125 of the interlayer insulating layer 115 that is not in contact with the wiring pattern 109. The passivation layer 106 is a surface layer, and the interlayer insulating layer 115 is a lower layer under the passivation layer 106.

FIGS. 6B and 6C are explanatory diagrams of a mark portion 105B. FIG. 6B is a plan view of a region of the passivation layer 106 including the mark portion 105B as viewed in the Z direction. FIG. 6C is a plan view of a region of the wiring pattern 109 and the interlayer insulating layer 115 including the mark portion 105B as viewed in the Z direction.

The mark portion 105B is a recess portion including the opening 108 of the passivation layer 106 (surface layer) and the interlayer insulating layer 115 (lower layer) adjacent to the passivation layer 106. The passivation layer 106 and the opening 108 thereof are an example of a first portion, and the interlayer insulating layer 115 is an example of a second portion.

In the third embodiment, the mark portion 105B is a plus-shaped mark in plan view (as viewed in the Z direction).

The interlayer insulating layer 115 is a solid pattern having a larger area than the opening 108 as viewed in the Z direction. In the interlayer insulating layer 115, a region 143 having a plus shape as viewed in the Z direction as visually recognized through the opening 108 constitutes part of the mark portion 105B.

To be noted, the method for manufacturing the detection unit 300 according to the third embodiment is as described in the first embodiment, and the description thereof will be omitted.

In the third embodiment, the mark portion 105B can be visually recognized on the basis of the height difference between the passivation layer 106 and the interlayer insulating layer 115 at the opening 108. In addition, as compared with the first embodiment and the second embodiment, the mark portion 105B can be positioned regardless of the position of the wiring pattern 109, and therefore the degree of freedom of the layout of the mark portion 105B is high.

As described above, according to the third embodiment, a technique advantageous for the alignment between the radiation detector 1 and the shielding member 200 can be provided. Further, since the visibility of the mark portion 105B is high, the shielding member 200 can be aligned with the radiation detector 1 with high precision. In addition, as a result of the radiation being shielded by the shielding member 200, the circuit operation of the peripheral circuit portion 3 is stabilized, malfunction of the peripheral circuit portion 3 is suppressed, and occurrence of an image defect is also suppressed.

To be noted, various modifications may be made to the mark portion 105B of the third embodiment similarly to the first embodiment. For example, the mark portion 105B can be modified as in the modification examples illustrated in FIGS. 4A to 4F.

### Fourth Embodiment

A radiation detector according to a fourth embodiment will be described with reference to drawings. In the fourth embodiment, description of matter common to the first embodiment will be simplified or omitted, and difference from the first embodiment will be mainly described. The schematic configuration of the radiation detector 1 of the fourth embodiment is as described in the first embodiment with reference to FIGS. 1 and 2A. In addition, the schematic configuration of the detection unit 300 including the radiation detector 1 and the shielding member 200 of the fourth embodiment is as described in the first embodiment with reference to FIG. 2B.

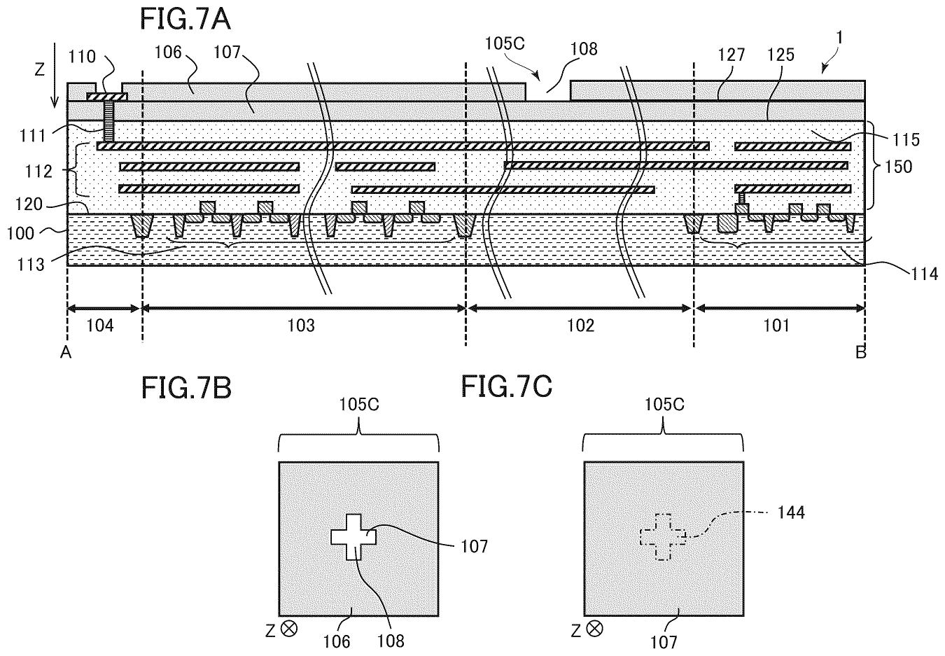

FIG. 7A is a section view of the radiation detector 1 taken along the line A-B of FIG. 2A.

The wiring structure body 150 of the fourth embodiment includes the interlayer insulating layer 115 formed from an insulator and the plurality of wiring layers (conductor layers) 112 disposed in the interlayer insulating layer 115. A passivation layer 107 is disposed on the interlayer insulating layer 115, and the passivation layer 106 is disposed on the passivation layer 107. To be noted, a wiring layer may be disposed on the interlayer insulating layer 115, that is, between the interlayer insulating layer 115 and the passivation layer 107. The passivation layer 107 is adjacent to the interlayer insulating layer 115. That is, the passivation layer 107 is in contact with the main surface 125 of the interlayer insulating layer 115. The passivation layer 106 is adjacent to the passivation layer 107. That is, the passivation layer 106 is in contact with a main surface 127 of the passivation layer 107. To be noted, a pad electrode 110 is disposed at a position on the passivation layer 107 corresponding to an opening of the passivation layer 106. The passivation layer 106 is a surface layer, and the passivation layer 107 is a lower layer under the passivation layer 106. The passivation layer 106 is an example of a first passivation layer, and the passivation layer 107 is an example of a second passivation layer.

FIGS. 7B and 7C are explanatory diagrams of a mark portion 105C. FIG. 7B is a plan view of a region of the passivation layer 106 including the mark portion 105C as viewed in the Z direction. FIG. 7C is a plan view of a region of the passivation layer 107 including the mark portion 105C as viewed in the Z direction.

The mark portion 105C is a recess portion including the opening 108 of the passivation layer 106 (surface layer) and the passivation layer 107 (lower layer) adjacent to the passivation layer 106. The passivation layer 106 and the opening 108 thereof are an example of a first portion, and the passivation layer 107 is an example of a second portion.

In the fourth embodiment, the mark portion 105C is a plus-shaped mark in plan view (as viewed in the Z direction). In the fourth embodiment, the opening 108 that is a through hole penetrating the passivation layer 106 has a plus shape as viewed in the Z direction.

The passivation layer 107 is a solid pattern having a larger area than the opening 108 as viewed in the Z direction. In the passivation layer 107, the opening 108 and a region 144 having a plus shape as viewed in the Z direction as visually recognized through the opening 108 constitute part of the mark portion 105C.

Examples of the material of the passivation layers 106 and 107 include organic insulating materials such as silicon oxide, silicon nitride, silicon oxynitride, and polyimide, and combinations of two or more of these materials.

In addition, the material of the passivation layer 107 is preferably different from the material of the passivation layer 106. For example, the passivation layer 107 may be an etching stopping layer used when forming the opening 108 in the passivation layer 106 by etching in the photolithography process. In this case, the processing for forming the opening 108 in the passivation layer 106 becomes easier. To be noted, in the case where the passivation layer 107 is the etching stopping layer, another insulating layer may be provided between the passivation layer 107 and the interlayer insulating layer 115.

To be noted, the method for manufacturing the detection unit 300 according to the fourth embodiment is as described in the first embodiment, and the description thereof will be omitted.

In the fourth embodiment, the mark portion 105C can be visually recognized on the basis of the height difference between the passivation layer 106 and the passivation layer 107 at the opening 108. In addition, the surface side of the radiation detector 1 of the fourth embodiment can be protected more strongly by the passivation layers 106 and 107 than in the radiation detector 1 of the first to third embodiments.

As described above, according to the fourth embodiment, a technique advantageous for the alignment between the radiation detector 1 and the shielding member 200 can be provided. Further, since the visibility of the mark portion 105C is high, the shielding member 200 can be aligned with the radiation detector 1 with high precision. In addition, as a result of the radiation being shielded by the shielding member 200, the circuit operation of the peripheral circuit portion 3 is stabilized, malfunction of the peripheral circuit portion 3 is suppressed, and occurrence of an image defect is also suppressed.

To be noted, various modifications may be made to the mark portion 105C of the fourth embodiment similarly to the first embodiment. For example, the mark portion 105C can be modified as in the modification examples illustrated in FIGS. 4A to 4F.

### Fifth Embodiment

A radiation detector according to a fifth embodiment will be described with reference to drawings. In the fifth embodiment, description of matter common to the first embodiment will be simplified or omitted, and difference from the first embodiment will be mainly described. The schematic configuration of the radiation detector 1 of the fifth embodiment is as described in the first embodiment with reference to FIGS. 1 and 2A. In addition, the schematic configuration of the detection unit 300 including the radiation detector 1 and the shielding member 200 of the fifth embodiment is as described in the first embodiment with reference to FIG. 2B.

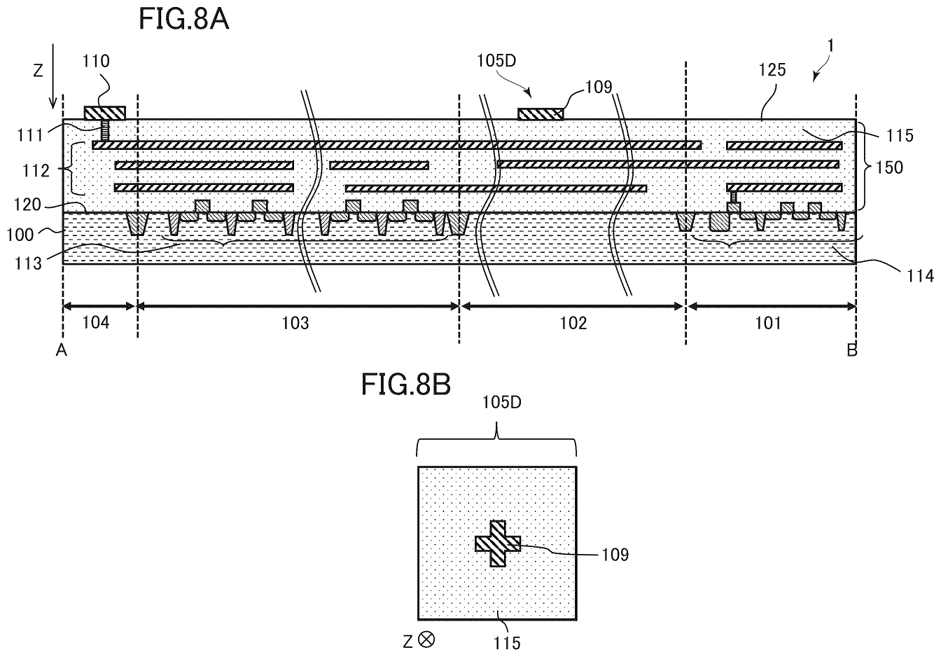

FIG. 8A is a section view of the radiation detector 1 taken along the line A-B of FIG. 2A. The radiation detector 1 of the fifth embodiment does not include a passivation layer. That is, the radiation detector 1 of the fifth embodiment is used for a use not requiring a passivation layer.

The wiring structure body 150 of the fifth embodiment includes the interlayer insulating layer 115 formed from an insulator and the plurality of wiring layers (conductor layers) 112 disposed in the interlayer insulating layer 115. In addition, the wiring pattern 109 serving as part of the outermost wiring layer is disposed on the interlayer insulating layer 115. The wiring pattern 109 is adjacent to the interlayer insulating layer 115. That is, he wiring pattern 109 is in contact with the main surface 125 of the interlayer insulating layer 115. The wiring pattern 109 is a surface layer, and the interlayer insulating layer 115 is a lower layer under the wiring pattern 109.

FIG. 8B is an explanatory diagram of the mark portion 105D. FIG. 8B is a plan view of a region of the wiring pattern 109 and the interlayer insulating layer 115 including the mark portion 105D as viewed in the Z direction.

The mark portion 105D includes the wiring pattern 109 (surface layer). The wiring pattern 109 is an example of a first portion. In the fifth embodiment, the mark portion 105D is the wiring pattern 109. That is, in the fifth embodiment, the mark portion 105D does not include the interlayer insulating layer 115 serving as a lower layer under the wiring pattern 109.

In the fifth embodiment, the mark portion 105D, that is, the wiring pattern 109 is a plus-shaped mark in plan view (as viewed in the Z direction). The interlayer insulating layer 115 is a solid pattern having a larger area than the wiring pattern 109 as viewed in the Z direction. Therefore, the contrast between the wiring pattern 109 and the interlayer insulating layer 115 becomes clear, and the wiring pattern 109 can be visually recognized easily. To be noted, the wiring pattern 109 may be connected to the wiring layer 112 through a via, or may be not connected to the wiring layer 112.

To be noted, the method for manufacturing the detection unit 300 according to the fifth embodiment is as described in the first embodiment, and the description thereof will be omitted.

In the fifth embodiment, as a result of omitting the passivation layer or the passivation layer and the via, the energy loss of the radiation passing through the radiation detector 1 can be reduced, and scattering of the radiation can be reduced. For example, in the case where the radiation is an electron beam, this effect is particularly prominent.

As described above, according to the fifth embodiment, a technique advantageous for the alignment between the radiation detector 1 and the shielding member 200 can be provided. Further, since the visibility of the mark portion 105D is high, the shielding member 200 can be aligned with the radiation detector 1 with high precision. In addition, as a result of the radiation being shielded by the shielding member 200, the circuit operation of the peripheral circuit portion 3 is stabilized, malfunction of the peripheral circuit portion 3 is suppressed, and occurrence of an image defect is also suppressed.

To be noted, various modifications may be made to the mark portion 105D of the fifth embodiment similarly to the first embodiment. For example, the mark portion 105D can be modified as in the modification examples illustrated in FIGS. 4A to 4F.

### Sixth Embodiment

A radiation detector and a detection unit according to a sixth embodiment will be described with reference to drawings. In the sixth embodiment, description of matter common to the first embodiment will be simplified or omitted, and difference from the first embodiment will be mainly described.

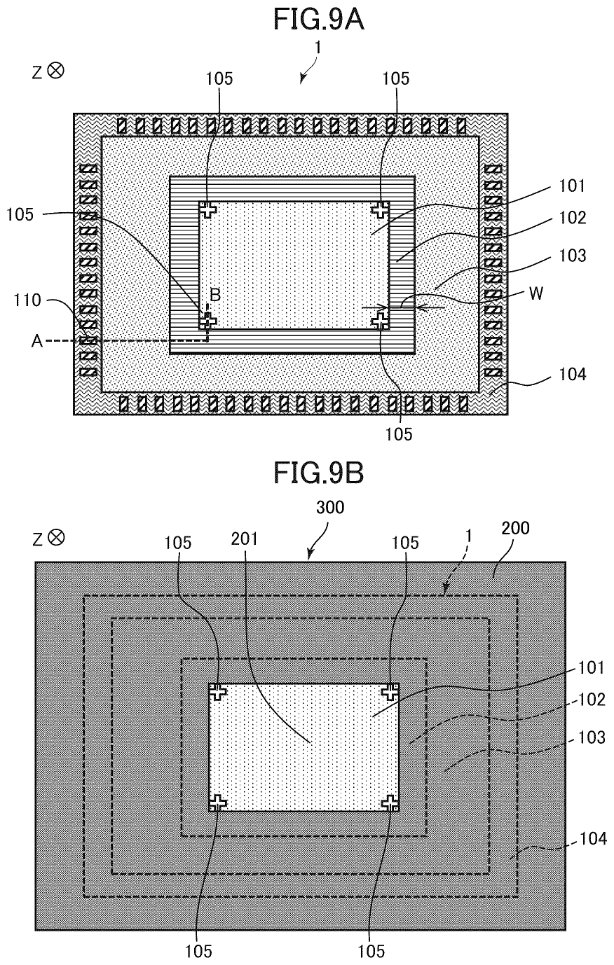

FIG. 9A is a plan view of the radiation detector 1 according to the sixth embodiment. FIG. 9A illustrates a surface of the radiation detector 1 on the radiation incident side (incident surface) in plan view, that is, as viewed in the Z direction. To be noted, the circuit arrangement of the radiation detector 1 of the sixth embodiment is as described in the first embodiment with reference to FIG. 1, and will be given the same reference signs and description thereof will be omitted.

The radiation detector 1 is segmented into a plurality of regions as viewed in the Z direction. Similarly to the first embodiment, the plurality of regions include the pixel region 101, the buffer region 102, the peripheral circuit region 103, and the pad region 104. The pixel region 101 is an example of a first region. The peripheral circuit region 103 is an example of a second region. The buffer region 102 is an example of a third region. A plurality of mark portions, for example, four mark portions 105 are disposed in the pixel region 101 as viewed in the Z direction. The mark portions 105 are each disposed in the vicinity of corresponding one of the four corner portions of the pixel region 101 as viewed in the Z direction.

FIG. 9B is a plan view of a detection unit 300 according to the sixth embodiment. The detection unit 300 includes the radiation detector 1 and the shielding member 200. The shielding member 200 is formed from a metal member capable of shielding a radiation. The shielding member 200 is disposed on the radiation incident side of the radiation detector 1. The shielding member 200 is disposed at a position overlapping with the entirety of the peripheral circuit region 103, that is, the entirety of the peripheral circuit portion 3 illustrated in FIG. 1 as viewed in the Z direction such that no radiation is radiated onto the peripheral circuit region 103.

The opening 201 that is a through hole is provided in the shielding member 200. The opening 201 is formed at a position corresponding to the pixel array 2 such that the radiation is incident on the pixel array 2.

The opening 201 has a rectangular shape having an area approximately equal to the area of the pixel region 101 as viewed in the Z direction. That is, the pixel array 2 disposed in the pixel region 101 does not overlap with the shielding member 200 as viewed in the Z direction. The pixel array 2 (FIG. 1) disposed in the pixel region 101 is irradiated with a radiation having passed through the opening 201 of the shielding member 200. The mark portions 105 are used for aligning the shielding member 200 with the radiation detector 1 such that the shielding member 200 does not overlap with the pixel array 2.

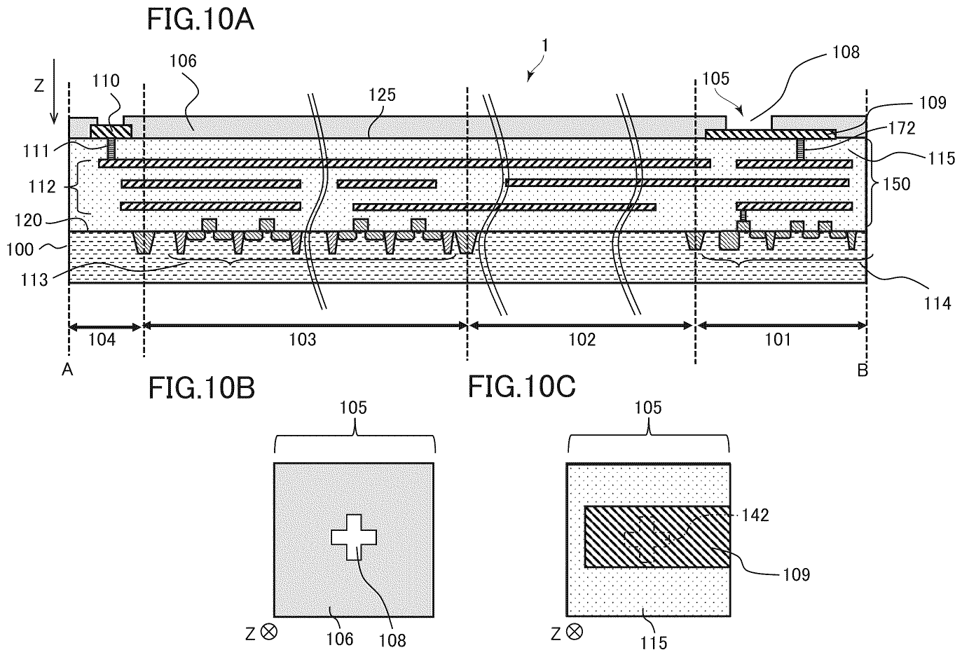

FIG. 10A is a section view of the radiation detector 1 taken along the line A-B of FIG. 9A. FIGS. 10B and 10C are explanatory diagrams of the mark portion 105 disposed in the pixel region 101. FIG. 10B is a plan view of a region of the passivation layer 106 including the mark portion 105 as viewed in the Z direction. FIG. 10C is a plan view of a region of the wiring pattern 109 and the interlayer insulating layer 115 including the mark portion 105 as viewed in the Z direction.

In the sixth embodiment, the mark portion 105 is a plus-shaped mark in plan view (as viewed in the Z direction). The mark portion 105 is constituted by the opening 108 of the passivation layer 106 and the wiring pattern 109 serving as part of the outermost wiring layer. In the sixth embodiment, the opening 108 is a through hole penetrating the passivation layer 106. The opening 108 has a plus shape as viewed in the Z direction.

The wiring pattern 109 is a solid pattern having a larger area than the opening 108 as viewed in the Z direction. In the wiring pattern 109, the region 142 in the wiring pattern 109 having a plus shape as viewed in the Z direction and visually recognized through the opening 108 constitutes part of the mark portion 105.

As described above, the mark portion 105 is a recess portion including the opening 108 of the passivation layer 106 and the wiring pattern 109 that is a lower layer adjacent to the passivation layer 106. The passivation layer 106 and the opening 108 thereof are an example of a first portion, and the wiring pattern 109 is an example of a second portion.

The radiation passes through both the opening 108 and the wiring pattern 109 included in the mark portion 105. Therefore, the mark portion 105 may be disposed on the detection diode included in the pixel 20 that is an effective pixel disposed in the pixel region 101. The radiation passes through the mark portion 105 and reaches the detection diode included in the pixel 20 that is an effective pixel, and therefore the radiation detector 1 can perform imaging even in the case where the mark portion 105 is in the pixel region 101.

According to the configuration described above, the radiation detector 1 can reduce the width W of the buffer region 102, for example, reduce the width W to a value of 200 μm or more and 2000 μm or less, and thus the radiation detector 1 can be miniaturized. Further, the peripheral circuit portion 3 (FIG. 1) disposed in the peripheral circuit region 103 can be more strongly shielded from the radiation by the shielding member 200.

A manufacturing method for the detection unit 300 illustrated in FIG. 9B will be described. First, the radiation detector 1 and the shielding member 200 are prepared.

Next, the mark portion 105 is measured by using a measurement apparatus such as a microscope from the incident surface side of the radiation detector 1. In the sixth embodiment, the mark portion 105 can be easily optically measured, and the focus of the measurement apparatus can be also easily adjusted.

Next, the shielding member 200 is aligned with the radiation detector 1 such that the peripheral circuit region 103 of the radiation detector 1 is covered by the shielding member 200 as viewed in the Z direction. Specifically, the shielding member 200 is aligned with the radiation detector 1 such that the shielding member 200 does not overlap with each mark portion 105 and does not overlap with the pixel array 2 (pixel region 101) as viewed in the Z direction, and then the shielding member 200 and the radiation detector 1 are fixed.

At the time of this alignment, since the visibility of the mark portion 105 is high, the shielding member 200 can be aligned with the radiation detector 1 with high precision. For example, by aligning two sides of the opening 201 of the shielding member 200 with two sides of the mark portion 105 having a plus shape as illustrated in FIG. 9B, the shielding member 200 can be aligned with the radiation detector 1 with high precision. To be noted, electrical correction of electrically selecting an imaging region of the pixel array 2 (FIG. 1) disposed in the pixel region 101 may be performed in accordance with variation of alignment between the opening 201 of the shielding member 200 and the pixel region 101 as viewed in the Z direction.

As described above, according to the sixth embodiment, a technique advantageous for alignment between the radiation detector 1 and the shielding member 200 is provided. Further, since the visibility of the mark portion 105 is high, the shielding member 200 can be aligned with the radiation detector 1 with high precision. In addition, as a result of the radiation being shielded by the shielding member 200, the circuit operation of the peripheral circuit portion 3 is stabilized, malfunction of the peripheral circuit portion 3 is suppressed, and occurrence of an image defect is also suppressed.

### Modification Examples of Sixth Embodiment

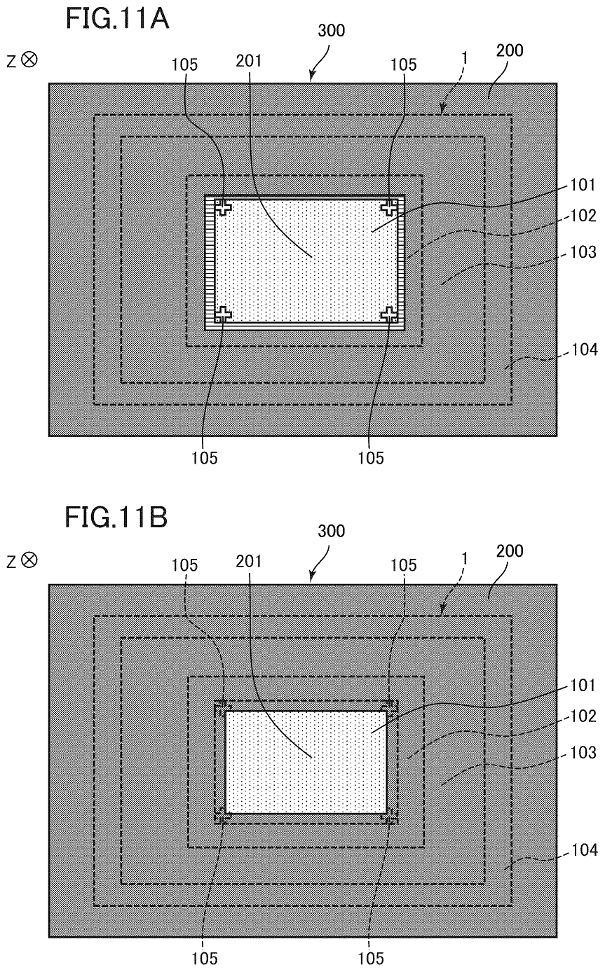

Modification examples of the detection unit 300 of the sixth embodiment will be described. FIGS. 11A and 11B are each a plan view of the detection unit 300 of a modification example.

The modification example illustrated in FIG. 11A will be described. As illustrated in FIG. 11A, the mark portions 105 are disposed in the pixel region 101 as viewed in the Z direction. In the modification example illustrated in FIG. 11A, the area of the opening 201 is larger than the area of the pixel region 101 and smaller than the area of a portion surrounded by an outer shape of the buffer region 102 as viewed in the Z direction. That is, the size of the opening 201 of the shielding member 200 is set such that the shielding member 200 overlaps with the entirety of the peripheral circuit portion 3 and does not overlap with the pixel array 2 when the shielding member 200 is positioned such that all the plurality of mark portions 105 are visible through the opening 201 as viewed in the Z direction. Further, when the shielding member 200 is positioned so as not to overlap with any of the mark portions 105 as viewed in the Z direction, the shielding member 200 does not overlap with the pixel array 2 (FIG. 1) disposed in the pixel region 101. As described above, the size of the opening 201 does not have to be equal to the size of the pixel region 101.

The modification example illustrated in FIG. 11B will be described. As illustrated in FIG. 11B, the mark portions 105 are disposed in the pixel region 101 as viewed in the Z direction. In the modification example illustrated in FIG. 11B, the area of the opening 201 is smaller than the area of the pixel region 101. That is, the size of the opening 201 of the shielding member 200 is set to a size equal to or larger than the region of the pixels serving as effective pixels among the plurality of pixels 20 of the pixel array 2 as viewed in the Z direction.

When the shielding member 200 is positioned so as to overlap with part or all of the mark portions 105, all in FIG. 11B as viewed in the Z direction, the shielding member 200 does not overlap with the effective pixels included in the pixel array 2. At this time, the shielding member 200 overlaps with non-effective pixels as viewed in the Z direction. As described above, the boundary of the shielding member 200 may be set within the pixel region 101. At this time, electrical correction of electrically selecting an imaging region in the pixel region 101 may be performed in accordance with variation of alignment of the shielding member 200.

To be noted, various modifications may be made to the mark portion 105 of the sixth embodiment similarly to the first embodiment. For example, the mark portion 105 can be modified as in the modification examples illustrated in FIGS. 4A to 4F.

In addition, in the radiation detector 1 of the sixth embodiment, the mark portion 105 may be replaced by any of the mark portions 105A to 105D of the first to fifth embodiments.

### Seventh Embodiment

Configuration examples of the detection unit 300 including the radiation detector 1 and the shielding member 200 have been described in the first to sixth embodiments described above. In the seventh embodiment, a radiation imaging system including the detection unit 300 will be described.

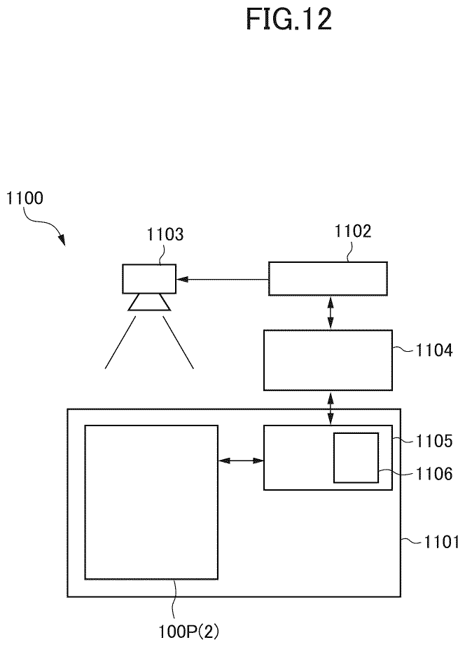

A radiation imaging system 1100 illustrated in FIG. 12 is a detection system including an imaging portion 1101 that is the detection unit 300 including the radiation detector 1 and the shielding member 200, an irradiation controller 1102, a radiation source 1103 serving as an energy beam radiating portion, and a computer 1104. The imaging portion 1101 includes an imaging panel 100P including the pixel array 2. The detection unit 300 including the radiation detector 1 described in any of the first to sixth embodiments can be used as the imaging portion 1101.

The radiation source 1103 starts emission of the radiation in accordance with an irradiation command from the irradiation controller 1102. The radiation emitted from the radiation source 1103 passes through an imaging target (subject) and is incident on the imaging panel 100P of the imaging portion 1101. The radiation source 1103 stops the emission of the radiation in accordance with a stop command from the irradiation controller 1102.

The imaging portion 1101 is, for example, a flat panel detector used for radiographing for medical image diagnosis or non-destructive inspection. The imaging panel 100P of the imaging portion 1101 may be formed in a plate shape having a size corresponding to the imaging target. For example, in the imaging panel 100P, 3300×2800 pixels are disposed on a 550 mm×445 mm substrate.

The imaging portion 1101 may have a configuration of a direct conversion type that converts the radiation into a signal charge by detection diodes provided in the pixel array 2 of the imaging panel 100P. In addition, the imaging portion 1101 may have a configuration of an indirect conversion type that coverts the radiation into fluorescent light by a scintillator layer provided in an upper layer of the pixel array 2 of the imaging panel 100P and converts the fluorescent light into a signal charge by the detection diodes of the pixel array 2.

The imaging portion 1101 includes the imaging panel 100P described above, a controller 1105 for controlling the imaging panel 100P, and a signal processing portion 1106 for processing a signal output from the imaging panel 100P. The signal processing portion 1106 may, for example, perform A/D conversion on the signal output from the imaging panel 100P, and output the converted signal to the computer 1104 as digital image data. In addition, the signal processing portion 1106 may, for example, generate a stop signal for stopping the emission of the radiation from the radiation source 1103 on the basis of the signal output from the imaging panel 100P. The stop signal is supplied to the irradiation controller 1102 via the computer 1104, and the irradiation controller 1102 transmits a stop command to the radiation source 1103 in response to the stop signal.

The controller 1105 can be constituted by, for example, a programmable logic device (PLD) such as a field programmable gate array (FPGA), an application specific integrated circuit (ASIC), a general-purpose computer including a program, or a combination of part or all of these.

Although the signal processing portion 1106 is described as provided in the controller 1105 or as part of functions of the controller 1105 in the seventh embodiment, the configuration is not limited to this. The controller 1105 and the signal processing portion 1106 may be provided separately. Further, the signal processing portion 1106 may be provided separately from the imaging portion 1101. For example, the computer 1104 may have the function of the signal processing portion 1106. Therefore, the signal processing portion 1106 can be included in the radiation imaging system 1100 as a signal processing apparatus that processes the signal output from the imaging portion 1101.

The computer 1104 can perform control of the imaging portion 1101 and the irradiation controller 1102, and processing for receiving the radiation image data from the imaging portion 1101 and displaying the radiation image data as a radiation image. In addition, the computer 1104 can function as an input portion for inputting a condition for the user to capture a radiation image.

For example, the irradiation controller 1102 includes an irradiation switch, and when the irradiation switch is turned on by the user, transmits an irradiation command to the radiation source 1103, and transmits a start notification indicating the start of radiation of the radiation to the computer 1104. The computer 1104 having received the start notification notifies the controller 1105 of the imaging portion 1101 about the start of radiation of the radiation in response to the start notification. In accordance with this, the controller 1105 generates a signal corresponding to the incident radiation in the imaging panel 100P.

### Eighth Embodiment

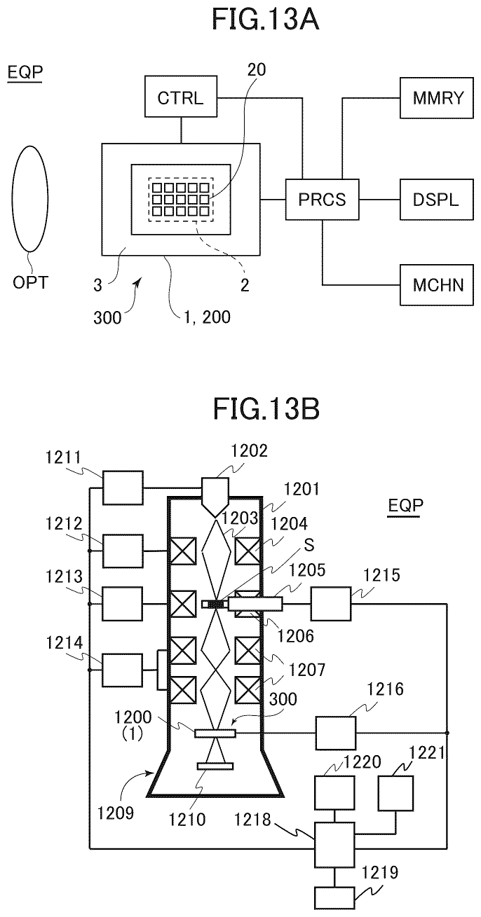

In the eighth embodiment, another example of a radiation imaging system will be described. FIG. 13A illustrates equipment EQP serving as a radiation imaging system. The equipment EQP includes the detection unit 300 including the radiation detector 1 and the shielding member 200.

The radiation detector 1 includes the pixel array 2 in which the pixels 20 are arranged in a matrix shape, and the peripheral circuit portion 3 disposed therearound. The peripheral circuit portion 3 includes a plurality of peripheral circuits. Further, the shielding member 200 is disposed on the radiation incident side of the radiation detector 1.

The equipment EQP can further include at least one of an optical system OPT, a control apparatus CTRL, a processing apparatus PRCS, a display apparatus DSPL, a storage apparatus MMRY, and a machine apparatus MCHN. The optical system OPT focuses the radiation on the radiation detector 1, and examples thereof include lenses, shutters, and mirrors. The optical system OPT may focus a corpuscular ray such as an electron beam or a proton beam on the radiation detector 1 depending on the kind or radiation that is used. The control apparatus CTRL controls the radiation detector 1, and is, for example, an ASIC. The processing apparatus PRCS processes the signal output from the radiation detector 1, and is an apparatus such as a CPU or an ASIC for constituting an analog front end (AFE) or a digital front end (DFE). The display apparatus DSPL is an apparatus such as an EL display apparatus or a liquid crystal display apparatus that displays the information obtained by the radiation detector 1 in the form of a visible image or the like. The storage apparatus MMRY is a magnetic device, a semiconductor device, or the like that stores information obtained by the radiation detector 1. The storage apparatus MMRY is a volatile memory such as a static random access memory (SRAM) or a dynamic random access memory (DRAM), or a nonvolatile memory such as a flash memory or a hard disk drive. The machine apparatus MCHN includes a movable portion or a propelling portion such as a motor or an engine.

The equipment EQP displays a signal output from the radiation detector 1 on the display apparatus DSPL, transmits the signal to the outside through a communication apparatus (not illustrated) included in the equipment EQP, and the like. Therefore, the equipment EQP preferably further includes the storage apparatus MMRY and the processing apparatus PRCS in addition to the storage circuit and the arithmetic operation circuit included in the radiation detector 1. The machine apparatus MCHN may be controlled on the basis of the signal output from the radiation detector 1.

The equipment EQP illustrated in FIG. 13A may be medical equipment such as an endoscope or radiation diagnosis equipment, measurement equipment such as a distance measurement sensor, or analysis equipment such as an electron microscope.

FIG. 13B is a schematic diagram illustrating a configuration of a transmission electron microscope (TEM) as an example of the equipment EQP. The equipment EQP as the electron microscope includes an electron beam source 1202 (electron gun) serving as an energy beam (electron beam) irradiation portion, an irradiation lens 1204, a vacuum chamber 1201 (lens barrel), an objective lens 1206, and a magnification lens system 1207. In addition, the equipment EQP includes a camera 1209 serving as an imaging portion. The camera 1209 includes the detection unit 300 including a direct radiation detector 1200 (direct electron detector) as the radiation detector 1 of a direct detection type. That is, the direct radiation detector 1200 corresponds to the radiation detector 1.

An electron beam 1203 that is an energy beam radiated from the electron beam source 1202 is focused by the irradiation lens 1204, and is radiated onto a sample S serving as an analysis target held by a sample holder. A space that the electron beam 1203 passes through is formed in the vacuum chamber 1201 (lens barrel), and this space is maintained under vacuum. The radiation detector 1 is disposed to face the vacuum space that the electron beam 1203 passes through. The electron beam 1203 having passed through the sample S is expanded by the objective lens 1206 and the magnification lens system 1207, and is projected onto the radiation detector 1. An electronic optical system for irradiating the sample S with an electron beam will be referred to as an irradiation optical system, and an electronic optical system for focusing the electron beam having passed through the sample S on the radiation detector 1 will be referred to as a focusing optical system.

The electron beam source 1202 is controlled by an electron beam source control apparatus 1211. The irradiation lens 1204 is controlled by an irradiation lens control apparatus 1212. The objective lens 1206 is controlled by an objective lens control apparatus 1213. The magnification lens system 1207 is controlled by a magnification lens system control apparatus 1214. A control mechanism 1205 of the sample holder is controlled by a holder control apparatus 1215 that controls the driving mechanism of the sample holder.

The electron beam 1203 having passed through the sample S is detected by the direct radiation detector 1200 of the camera 1209. The output signal from the direct radiation detector 1200 is processed by a signal processing apparatus 1216 and an image processing apparatus 1218 each serving as the processing apparatus PRCS, and thus an image signal is generated. The generated image signal (transmission electron image) is displayed on an image display monitor 1220 and an analysis monitor 1221 each corresponding to the display apparatus DSPL.

The camera 1209 is provided at a lower portion of the equipment EQP. At least part of the camera 1209 is provided in the vacuum chamber 1201 such that the part is exposed to the vacuum space formed in the vacuum chamber 1201.

The electron beam source control apparatus 1211, the irradiation lens control apparatus 1212, the objective lens control apparatus 1213, the magnification lens system control apparatus 1214, and the holder control apparatus 1215 are each connected to the image processing apparatus 1218. As a result of this, data can be mutually communicated therebetween to set the imaging conditions of the electron microscope. For example, the irradiation rate of the electron beam can be set to 0.5 electron/pix/frm or less.

In this case, the electron beam source control apparatus 1211 and the image processing apparatus 1218 function as control means for controlling the irradiation rate of the radiation. The drive control of the sample holder, setting of the observation conditions of each lens, and the like can be performed in accordance with a signal from the image processing apparatus 1218.

The operator prepares the sample S serving as an imaging target, and sets the imaging conditions by using an input apparatus 1219 connected to the image processing apparatus 1218. Predetermined data is respectively input to the electron beam source control apparatus 1211, the irradiation lens control apparatus 1212, the objective lens control apparatus 1213, and the magnification lens system control apparatus 1214 such that desired acceleration voltage, magnification, and observation mode can be obtained. In addition, the operator inputs conditions such as the number of continuous view images, imaging start position, and movement speed of the sample holder to the image processing apparatus 1218 by using the input apparatus 1219 such as a mouse, a keyboard, or a touch panel. The image processing apparatus 1218 may be configured to automatically set the conditions regardless of the input from the operator.

The systems described in the seventh embodiment and the eighth embodiment described above are merely examples, and the radiation detectors described in the first to sixth embodiments may be applied to a different system.

According to the present disclosure, a technique advantageous for alignment between a radiation detector and a shielding member can be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-190403, filed Nov. 7, 2023, which is hereby incorporated by reference herein in its entirety.

What is claimed is:

1. A radiation detector comprising, in plan view:
a first region including a pixel portion and configured to detect a radiation by the pixel portion, the pixel portion including a plurality of pixels;
a second region including a plurality of peripheral circuits; and
a third region provided between the first region and the second region,
wherein a mark portion is disposed in the first region or the third region, and
wherein the mark portion includes at least one of a first portion and a second portion, the first portion constituting a surface layer of the radiation detector, the second portion being a portion of a lower layer adjacent to the first portion.

2. The radiation detector according to claim 1,
wherein the surface layer is a passivation layer provided with an opening, and
wherein the mark portion includes the opening as the first portion.

3. The radiation detector according to claim 2,
wherein the opening is a through hole,
wherein the lower layer is a wiring layer including a wiring pattern, and
wherein the mark portion includes, as the second portion, a region of the wiring pattern, the region corresponding to the through hole.

4. The radiation detector according to claim 2,
wherein the opening is a through hole,
wherein the lower layer is an interlayer insulating layer, and
wherein the mark portion includes, as the second portion, a region of the interlayer insulating layer, the region corresponding to the through hole.

5. The radiation detector according to claim 2,
wherein the passivation layer is a first passivation layer,
wherein the opening is a through hole,
wherein the lower layer is a second passivation layer, and
wherein the mark portion includes, as the second portion, a region of the second passivation layer, the region corresponding to the through hole.

6. The radiation detector according to claim 5, wherein a material of the first passivation layer is different from a material of the second passivation layer.

7. The radiation detector according to claim 6, wherein the second passivation layer is an etching stopping layer.

8. The radiation detector according to claim 1,
wherein the surface layer is a wiring layer including a wiring pattern, and
wherein the mark portion includes the wiring pattern as the first portion.

9. The radiation detector according to claim 1,
wherein the surface layer is a passivation layer,
wherein the lower layer is a wiring layer including a wiring pattern covered by the passivation layer, and
wherein the mark portion includes the wiring pattern as the second portion.

10. The radiation detector according to claim 1, wherein a width of the third region is 200 μm or more and 2000 μm or less.

11. The radiation detector according to claim 1, wherein the mark portion includes a plus-shaped mark in the plan view.

12. The radiation detector according to claim 11, wherein the mark portion includes a mark surrounding the plus-shaped mark in the plan view.

13. The radiation detector according to claim 1, wherein the mark portion includes a plurality of marks.

14. A detection unit comprising:
the radiation detector according to claim 1; and
a shielding member disposed on a radiation incident side of the radiation detector and having an opening provided at a position corresponding to the pixel portion,
wherein the shielding member overlaps with entirety of the second region in the plan view.

15. The detection unit according to claim 14,
wherein the mark portion is disposed in the third region in the plan view, and
wherein the shielding member overlaps with part or entirety of the mark portion and does not overlap with the pixel portion in the plan view.

16. The detection unit according to claim 14,
wherein the mark portion is disposed in the first region in the plan view, and
wherein the shielding member does not overlap with the mark portion and the pixel portion in the plan view.

17. The detection unit according to claim 14,
wherein the mark portion of the radiation detector is disposed in the first region in the plan view, and
wherein the shielding member overlaps with part or entirety of the mark portion and does not overlap with an effective pixel in the pixel portion of the radiation detector in the plan view.

18. A radiation imaging system comprising:
a radiation source configured to irradiate an imaging target with a radiation; and
the detection unit according to claim 14.

19. A method for manufacturing a detection unit, the method comprising:
preparing the radiation detector according to claim 1;
measuring the mark portion of the radiation detector; and
aligning a shielding member with the radiation detector such that the second region of the radiation detector is covered by the shielding member in the plan view.
